(19) United States
(12) Patent Application Publication
(10) Pub. No.: US 2017/0358835 A1
(43) Pub. Date: Dec. 14, 2017

(54) MICROWAVE PLASMA PROCESSING APPARATUS AND MICROWAVE PLASMA PROCESSING METHOD

(71) Applicant: Tokyo Electron Limited, Tokyo (JP)

(72) Inventors: Toshio Nakanishi, Yamanashi (JP); Kouji Tanaka, Yamanashi (JP); Michitaka Aita, Yamanashi (JP); Takafumi Nogami, Yamanashi (JP)

(21) Appl. No.: 15/613,371

(22) Filed: Jun. 5, 2017

(30) Foreign Application Priority Data
Jun. 10, 2016 (JP) 2016-115931

(51) Int. Cl. H01P 1/04; G02B 6/12; H01J 37/32; H01P 3/16; C03C 23/00; H01L 21/3065; H01L 21/302

(52) U.S. Cl. CPC H01P 1/045; H01L 21/3065; G02B 6/12011; H01L 21/302; H01P 3/16; C03C 23/004; H01J 37/32357

(57) ABSTRACT

Disclosed is a microwave plasma processing apparatus including: a chamber that accommodates a workpiece; a microwave generating source that generates microwaves; a waveguide unit that guides the microwaves toward the chamber; a planar antenna made of a conductor having a plurality of slots that radiate the microwaves toward the chamber; a microwave-transmitting plate made of a dielectric material that constitutes a top wall of the chamber and transmits the microwaves radiated from the plurality of slots; a gas supply mechanism that supplies a gas into the chamber; and an exhaust mechanism that exhausts an atmosphere in the chamber. The planar antenna includes a plurality of slot groups each forming one unit including one or more of the slots, and the slots are formed so as to form an odd number of the slot groups equal to or more than three in a circumferential direction.

### CROSS-REFERENCE TO RELATED APPLICATIONS

This application is based on and claims priority from Japanese Patent Application No. 2016-115931 filed on Jun. 10, 2016 with the Japan Patent Office, the disclosure of which is incorporated herein in its entirety by reference.

### TECHNICAL FIELD

The present disclosure relates to a microwave plasma processing apparatus and a microwave plasma processing method.

### BACKGROUND

A plasma processing is an indispensable technique for manufacturing semiconductor devices. Recently, however, design rules of semiconductor elements constituting an LSI have been increasingly miniaturized due to a demand for high integration and high speed of the LSI, and the size of semiconductor wafers has been increased. Accordingly, it is requested that a plasma processing apparatus cope with such miniaturization and enlargement.

In the related art, a parallel plate type or inductively coupled plasma processing apparatus has been used as a plasma processing apparatus, but it is difficult to uniformly and rapidly perform a plasma processing on a large semiconductor wafer.

Therefore, an RLSA (registered trademark) microwave plasma processing apparatus attracts attention, which is capable of uniformly forming surface wave plasma of high density and low electron temperature (see, e.g., Japanese Patent Laid-Open Publication No. 2000-294550).

In the RLSA (registered trademark) microwave plasma processing apparatus, a planar antenna having a plurality of slots formed in a predetermined pattern is provided in an upper portion of a chamber, and microwaves guided from a microwave generating source are radiated from the slots of the antenna, and are transmitted through a top wall of a chamber made of a dielectric into the chamber, which is maintained in vacuum, to generate surface wave plasma in the chamber. Thus, the gas introduced into the chamber is turned into plasma to process a workpiece such as, for example, a semiconductor wafer.

Meanwhile, it is known that the microwave plasma has a plasma mode determined by the plasma density, and the plasma mode is represented by a solution of the Bessel function (see, e.g., H. Sugai et al., Plasma Sources Sci. Technol. 7(1998) pp 192-205). Therefore, in the RLSA (registered trademark) microwave plasma processing apparatus, plasma is generally generated by using a planar antenna in which an even number of slots corresponding to the solution of the Bessel function are formed in the circumferential direction.

### SUMMARY

According to a first aspect of the present disclosure, there is provided a microwave plasma processing apparatus including: a chamber that accommodates a workpiece; a microwave generating source that generates microwaves; a waveguide unit that guides the microwaves generated from the microwave generating source toward the chamber; a planar antenna made of a conductor having a plurality of slots that radiate the microwaves guided by the waveguide unit toward the chamber; a microwave-transmitting plate made of a dielectric material that constitutes a top wall of the chamber and transmits the microwaves radiated from the plurality of slots; a gas supply mechanism that supplies a gas into the chamber; and an exhaust mechanism that exhausts an atmosphere in the chamber. The planar antenna includes a plurality of slot groups each forming one unit including one or more of the slots, and the slots are formed so as to form an odd number of slot groups equal to or more than three in a circumferential direction.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a schematic configuration of a microwave plasma processing apparatus according to an exemplary embodiment of the present disclosure.

FIG. 2 is a plan view illustrating an exemplary planar antenna used in the microwave plasma processing apparatus of FIG. 1.

FIG. 3 is a view for explaining a plasma mode appearing in a TM11 mode.

FIG. 4 is a view for explaining the plasma mode in the case of the planar antenna of FIG. 2 in which the number of slot groups in the circumferential direction is seven.

FIG. 5 is a plan view illustrating a conventional planar antenna.

FIG. 6 is a view for explaining a method of calculating an oval skew.

FIG. 7 is a graph illustrating a relationship between the film quality of an obtained SiN film (the value of the refractive index RI) and the value of the oval skew with respect to the inventive example using the planar antenna having seven slot groups as illustrated in FIG. 2 and a conventional example using the planar antenna having eight slot groups as illustrated in FIG. 5.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The microwave plasma is formed with superposition of several plasma modes, and the plasma modes are a superposition of solutions of Bessel function. Thus, when plasma is generated by using a planar antenna having an even number of slot groups in the circumferential direction, a TM11 which is a low-order mode may be generated due to the superimposition of plasma modes.

The plasma in the TM11 mode adversely affects the uniformity in the circumferential direction. Thus, when the TM11 mode is generated, the uniformity of plasma and the uniformity of the process are adversely affected.

From the viewpoint of affinity of process integration, it has been recently required to perform a more uniform plasma processing in the circumferential direction of the semiconductor wafer than ever before. Therefore, it is necessary to minimize an uneven low-order mode like the TM11 mode as much as possible.

Accordingly, the present disclosure is to provide a microwave plasma processing apparatus and a microwave plasma processing method capable of suppressing the generation of low-order modes such as the TM11 mode and performing a plasma processing with high uniformity.

According to a first aspect of the present disclosure, there is provided a microwave plasma processing apparatus including: a chamber that accommodates a workpiece; a microwave generating source that generates microwaves; a waveguide unit that guides the microwaves generated from the microwave generating source toward the chamber; a planar antenna made of a conductor having a plurality of slots that radiate the microwaves guided by the waveguide unit toward the chamber; a microwave-transmitting plate made of a dielectric material that constitutes a top wall of the chamber and transmits the microwaves radiated from the plurality of slots; a gas supply mechanism that supplies a gas into the chamber; and an exhaust mechanism that exhausts an atmosphere in the chamber. The planar antenna includes a plurality of slot groups each forming one unit including one or more of the slots, and the slots are formed so as to form an odd number of the slot groups equal to or more than three in a circumferential direction.

According to a second aspect of the present disclosure, there is provided a microwave plasma processing method including: accommodating a workpiece in a chamber; guiding, by a waveguide unit, microwaves generated from a microwave generating source; radiating the microwaves guided by the waveguide unit from a plurality of slots formed in a planar antenna made of a conductor through a microwave-transmitting plate made of a dielectric constituting a top wall of the chamber; supplying, by a gas supply mechanism, a gas into the chamber to generate plasma in a lower portion of the microwave-transmitting plate by the microwaves; and performing a predetermined processing on the workpiece by the plasma. The planar antenna includes a plurality of slot groups each forming one unit including one or more of the slots, and the slots are formed so as to form an odd number of slot groups equal to or more than three in a circumferential direction.

In the present disclosure, the slots are formed so as to form a prime number of slot groups in the circumferential direction in the planar antenna. In this case, the number of the slot group in the circumferential direction is exemplified by seven.

The waveguide unit may include: a rectangular waveguide that propagates the microwaves generated from the microwave generating source in a TE mode; a mode converter that converts the TE mode to a TEM mode; and a coaxial waveguide that propagates the microwaves converted into the TEM mode toward the planar antenna.

In a microwave plasma processing, a film forming gas may be supplied from the gas supply mechanism into the chamber to form a predetermined film on the workpiece by plasma CVD. Specifically, the film forming gas supplied from the gas supply mechanism may include a silicon source gas and a nitrogen-containing gas, and a silicon nitride film may be formed on the workpiece. At this time, the silicon nitride film is formed at 1.7% or less in terms of oval skew which is an index of a circumferential film thickness distribution.

According to the present disclosure, the planar antenna includes a plurality of slot groups each forming one unit including one or more of the slots, and the slots are formed so as to form an odd number of slot groups equal to or more than three in a circumferential direction. Therefore, any low-order mode such as the TM11 that adversely affects the uniformity of plasma in the circumferential direction is not generated. Accordingly, the uniformity of the plasma in the circumferential direction and the uniformity of the plasma processing may be enhanced.

Hereinafter, exemplary embodiments of the present disclosure will be described in detail with reference to the drawings.

<Configuration of Microwave Plasma Processing Apparatus>

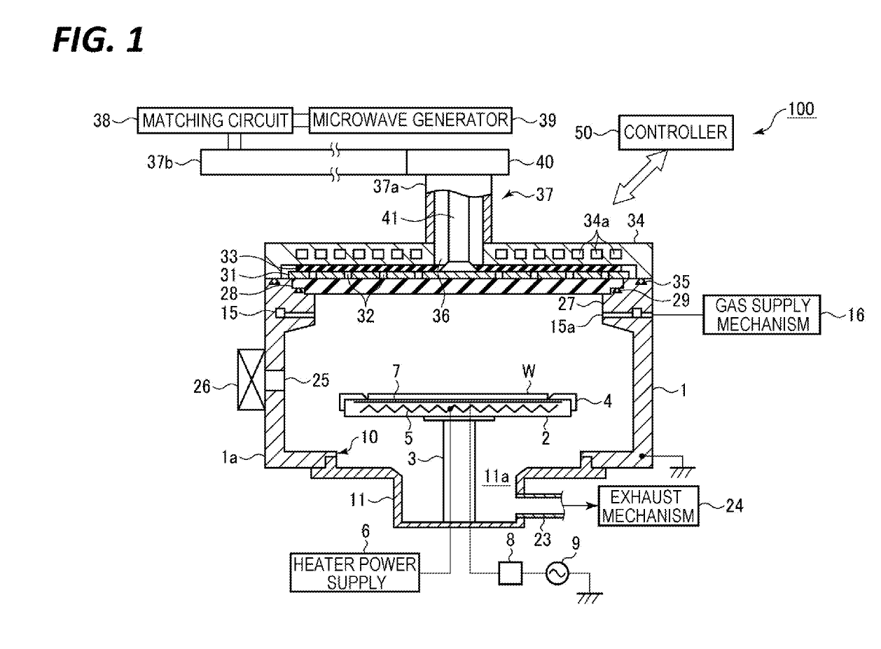

FIG. 1 is a cross-sectional view illustrating a schematic configuration of a microwave plasma processing apparatus according to an exemplary embodiment of the present disclosure. The microwave plasma processing apparatus of FIG. 1 is configured as an RLSA (registered trademark) microwave plasma processing apparatus.

As illustrated in FIG. 1, the microwave plasma processing apparatus 100 includes a substantially cylindrical chamber 1 which is airtightly configured and grounded. A circular opening 10 is formed in a substantially central portion of a bottom wall 1a of the chamber 1, and an exhaust chamber 11 is provided in the bottom wall 1a to communicate with the opening 10 and protrude downward.

A susceptor 2 made of ceramics (e.g., AlN) is provided in the chamber 1 to horizontally support a workpiece, for example, a semiconductor wafer (hereinafter referred to as a “wafer”) W. The susceptor 2 is supported by a cylindrical support member 3 made of ceramics (e.g., AlN) that extends upward from the center of the bottom of the exhaust chamber 11. A guide ring 4 is provided on the outer edge portion of the susceptor 2 to guide the wafer W. Further, a resistance heating type heater 5 is embedded in the susceptor 2. The heater 5 heats the susceptor 2 by supplying power from the heater power supply 6 to heat the wafer W. Further, an electrode 7 is embedded in the susceptor 2. The electrode 7 is connected with a high frequency power supply 9 for bias application via a matcher 8.

Wafer lift pins (not illustrated) for supporting and lifting the wafer W are provided in the susceptor 2 so as to protrude and retract from the surface of the susceptor 2.

An annular gas introduction portion 15 is provided in the side wall of the chamber 1, and gas ejection holes 15a are evenly formed in the gas introduction portion 15. The gas introduction portion 15 is connected with a gas supply mechanism 16.

The gas supply mechanism 16 supplies a gas for a plasma processing, and is configured to supply an appropriate gas depending on the plasma processing. The plasma processing is not particularly limited, but examples thereof may include plasma CVD. In the case of forming a silicon nitride film (SiN film), for example, by plasma CVD, a plasma generating gas, a Si source gas, and a nitrogen-containing gas are used as the gases supplied from the gas supply mechanism 16. Examples of the plasma generating gas include a rare gas such as, for example, Ar gas. Examples of the Si source gas include monosilane (SiH₄) and disilane (Si₂H₆). Examples of the nitrogen-containing gas include N₂ gas and ammonia (NH₃). These gases are supplied to the gas introduction portion 15 from respective gas supply sources at flow rates independently controlled by flow rate controllers such as, for example, mass flow controllers via separate pipes. The plasma generating gas is not indispensable.

A second gas introduction portion (e.g., a shower plate) may be provided below the gas introduction portion 15 so that a gas which may not be completely dissociated by plasma (e.g., a silicon source gas) is supplied from the second gas introduction portion to a region closer to the wafer W where the electron temperature is lower.

An exhaust pipe 23 is connected to a lateral side of the exhaust chamber 11, and an exhaust mechanism 24 including, for example, a vacuum pump or an automatic pressure control valve is connected to the exhaust pipe 23. The vacuum pump of the exhaust mechanism 24 is operated such that the gas in the chamber 1 is uniformly discharged into a space 11a of the exhaust chamber 11 and exhausted through the exhaust pipe 23, and the inside of the chamber 1 is controlled to a predetermined degree of vacuum by the automatic pressure control valve.

The side wall of the chamber 1 is provided with a carry-in/out port 25 that carries a wafer W into/out of a conveyance chamber (not illustrated) adjacent to the plasma processing apparatus 100, and a gate valve 26 that opens and closes the carry-in/out port 25.

The upper portion of the chamber 1 is configured as an opening portion, and the peripheral portion of the opening portion is configured as a ring-shaped support 27. A disc-shaped microwave-transmitting plate 28 made of a dielectric material (e.g., quartz or Al₂O₃) is airtightly provided in the support 27 through a sealing member 29. Accordingly, the inside of the processing container 1 is airtightly maintained.

A disc-shaped planar antenna 31 corresponding to the microwave transmitting plate 28 is provided above the microwave-transmitting plate 28 so as to be in close contact with the microwave-transmitting plate 28. The planar antenna 31 is locked to the upper end of the side wall of the chamber 1. The planar antenna 31 is a disc made of a conductive material.

For example, the planar antenna 31 is formed of a copper or aluminum plate whose surface is silver- or gold-plated, and has a configuration in which a plurality of slots 32 for radiating microwaves are formed so as to penetrate therethrough. The details of the planar antenna 31 will be described later.

A slow-wave plate 33 made of a dielectric material having a dielectric constant larger than that of vacuum (e.g., quartz or a resin such as polytetrafluoroethylene or polyimide) is closely attached to the upper surface of the planar antenna 31. The slow-wave plate 33 has a function of making the wavelength of the microwave shorter than that in the vacuum to reduce the size of the planar antenna 31.

The planar antenna 31 and the microwave-transmitting plate 28 are in close contact with each other. In addition, the slow-wave plate 33 and the planar antenna 31 are also in close contact with each other. Further, the thicknesses of the microwave-transmitting plate 28 and the slow-wave plate 33 are adjusted such that an equivalent circuit formed with the slow-wave plate 33, the planar antenna 31, the microwave-transmitting plate 28, and the plasma satisfies the resonance condition. The phase of the microwaves may be adjusted by adjusting the thickness of the slow-wave plate 33. Thus, when the thickness is adjusted such that the joint portion of the planar antenna 31 becomes an “antinode” of the standing waves, reflection of the microwaves is minimized, and radiation energy of the microwaves is maximized. Further, when the slow-wave plate 33 and the microwave-transmitting plate 28 are made of the same material, interface reflection of the microwaves may be suppressed.

The planar antenna 31 and the microwave-transmitting plate 28, and the slow-wave plate 33 and the planar antenna 31 may be spaced apart from each other.

A shield cover 34 made of a metal material (e.g., aluminum, stainless steel, or copper) is provided on the upper surface of the chamber 1 to cover the planar antenna 31 and the slow-wave plate 33. The upper surface of the chamber 1 and the shield cover 34 are sealed by a seal member 35. The shield cover 34 includes a cooling water flow path 34a formed therein, so that cooling water flows therethrough to cool the shield cover 34, the slow-wave plate 33, the planar antenna 31, and the microwave-transmitting plate 28. The shield cover 34 is grounded.

An opening 36 is formed in the center of the upper wall of the shield cover 34, and a waveguide 37 is connected to the opening. A microwave generator 39 is connected to an end portion of the waveguide 37 via a matching circuit 38. Therefore, microwaves with, for example, a frequency of 2.45 GHz generated by the microwave generator 39 are propagated to the planar antenna 31 via the waveguide 37. Various frequencies such as, for example, 8.35 GHz, 1.98 GHz, 860 MHz, or 915 MHz may be used as the frequency of the microwave.

The waveguide 37 includes a coaxial waveguide 37a having a circular cross section and extending upward from the opening 36 of the shield cover 34 and a rectangular waveguide 37b extending in the horizontal direction and connected to the upper end portion of the coaxial waveguide 37a via a mode converter 40. The mode converter 40 between the rectangular waveguide 37b and the coaxial waveguide 37a has a function of converting the microwave propagated in the TE mode in the rectangular waveguide 37b to the TEM mode. An inner conductor 41 extends in the center of the coaxial waveguide tube 37a, and the lower end portion of the inner conductor 41 is connected and fixed to the center of the planar antenna 31. Therefore, the microwaves are uniformly and efficiently propagated to the planar antenna 31 via the inner conductor 41 of the coaxial waveguide 37a.

The plasma processing apparatus 100 includes a controller 50. The controller 50 includes a main controller having a CPU (computer) that controls respective components of the microwave plasma processing apparatus 100, for example, the microwave generator 39, the heater power supply 6, the high frequency power supply 9, the exhaust mechanism 24, and a valve or a mass flow controller of the gas supply mechanism 16, an input device (e.g., a keyboard and a mouse), an output device (e.g., a printer), a display device (e.g., a display), and a storage device (e.g., a storage medium). The main controller of the controller 50 causes the microwave plasma processing apparatus 100 to execute a predetermined operation based on a processing recipe stored in the storage medium built in the storage device or a storage medium set in the storage device.

<Planar Antenna>

Next, the planar antenna 31 will be described in detail.

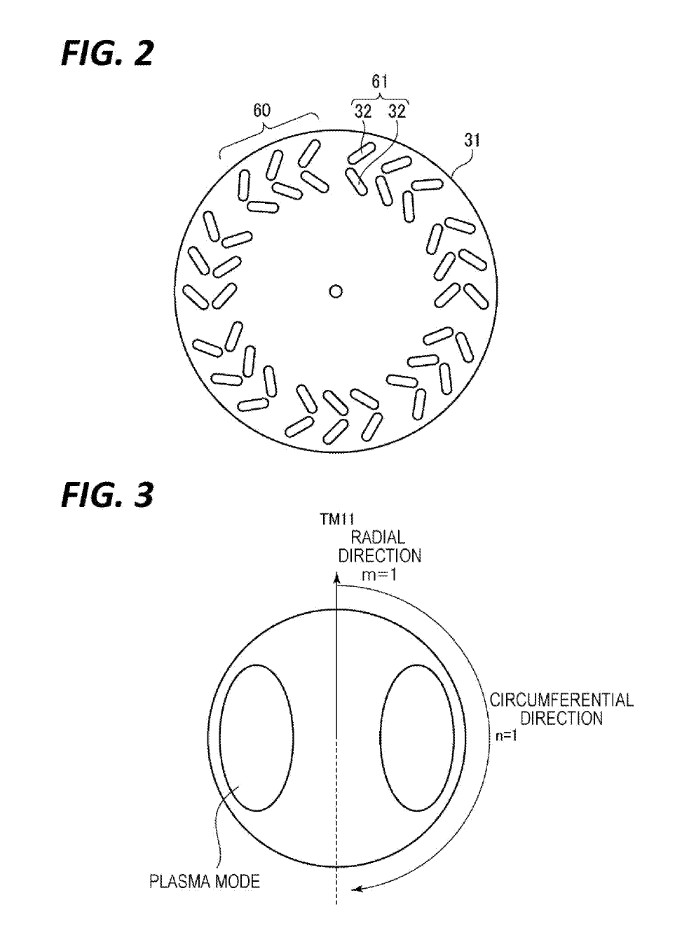

FIG. 2 is a plan view illustrating an exemplary planar antenna used in the microwave plasma processing apparatus of FIG. 1.

In the exemplary embodiment, the slots 32 are provided in the planar antenna 31 such that the number of slot groups in the circumferential direction is an odd number of three or more. A slot group includes one or more of slots and forms one unit. In this example, as illustrated in FIG. 2, the planar antenna 31 has seven slot groups 60 in the circumferential direction. Specifically, one slot 32 and the other slot 32 are arranged in a truncated chevron shape to form a slot pair 61, and three slot pairs 61 constitute one slot group 60.

In the case of having three or more slot groups in the circumferential direction, there is a tendency to induce high-order mode plasma corresponding to the slot groups. However, when the number of the slot groups is even, a TM11, which is a low-order mode that adversely affects the uniformity of the plasma, is generated, in addition to the high-order mode, due to the superposition of the plasma modes.

On the other hand, when the number of slot groups in the circumferential direction is odd, basically no lower order mode than the number of slot groups is generated. Thus, no TM11 mode is generated. Specifically, when the number of slot groups in the circumferential direction is a prime number, a lower order mode than the number of slot groups is hardly generated. Thus, the number of slot groups may be odd and prime. In the example of FIG. 2, since the number of the slot groups 60 is seven which is an odd and prime number, a lower order mode than the number of the slot group is not generated, and thus the TM11 mode is not generated either.

When the slots 32 are present separately, it is assumed that each slot constitutes a slot group. Thus, the number of slots 32 is the number of slot groups. In a case where there are a plurality of circumferential portions in which a plurality of slots are arranged in the circumferential direction in the radial direction, that is, in the case where the circumferential portions are formed in multiple, the number of slot groups of the circumferential portion having the smallest number of slot groups is set as the number of slot groups in the circumferential direction of the planar antenna 31.

<Operation of Microwave Plasma Processing Apparatus>

Next, descriptions will be made on the operation of the microwave plasma processing apparatus 100 configured as described above.

First, the gate valve 26 is opened, and a wafer W as a workpiece is carried into the chamber 1 from the carry-in/out port 25 and placed on the susceptor 2.

Then, a predetermined gas is introduced into the chamber 1 from the gas supply mechanism 16 via the gas introduction portion 15, and microwaves of predetermined power from the microwave generator 39 are guided to the waveguide 37 via the matching circuit 38. The microwaves guided to the waveguide 37 are propagated through the rectangular waveguide 37b in the TE mode. The TE mode of the microwaves is converted into the TEM mode by the mode converter 40, and the microwaves are propagated through the coaxial waveguide 37a in the TEM mode. Then, the microwaves in the TEM mode are transmitted through the slow-wave plate 33, the slots 32 of the planar antenna 31, and the microwave-transmitting plate 28, and are radiated into the chamber 1.

The microwaves spread as a surface wave only in a region directly under the microwave-transmitting plate 28, so that surface wave plasma is generated. Then, the plasma is dispersed downward and becomes plasma of high electron density and low electron temperature in the region where the wafer W is arranged.

At this time, when the planar antenna 31 has three or more slot groups, the surface wave plasma generated by the microwaves radiated into the chamber 1 has many positions corresponding to the slot groups having a high electric field strength. Thus, there is a tendency to induce high-order mode plasma. However, when the number of the slot groups is even, a TM11, which is a low-order mode, is generated due to the superposition of the plasma modes. The TM11 is a mode in which one plasma mode is generated in the radial direction and one plasma mode is generated on a half circumference in the circumferential direction, and two plasma modes appears as illustrated in FIG. 3. Thus, when the TM11 is generated, the plasma becomes non-uniform.

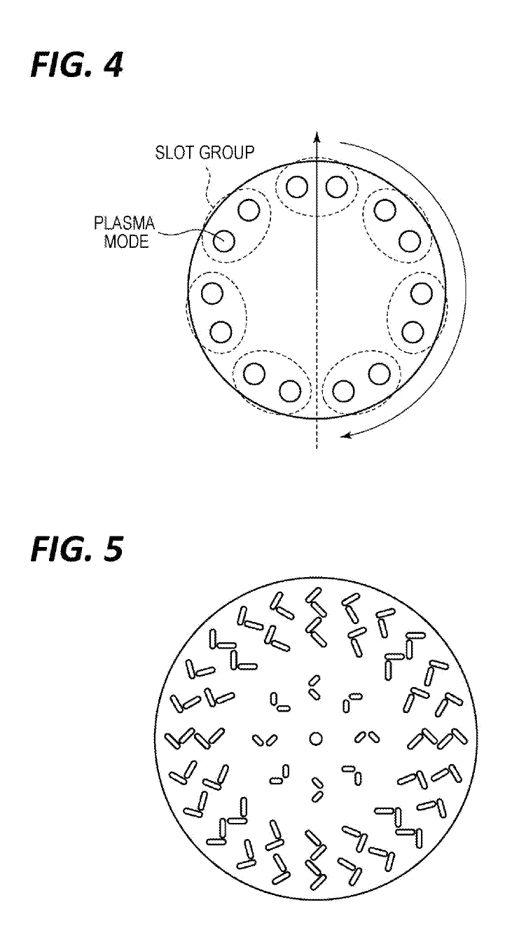

On the other hand, when the number of the slot groups in the circumferential direction is an odd number of three or more, the TM11 is not generated even by superimposing a plurality of plasma modes generated corresponding to the number of the slot groups. In the planar antenna 31 of this example, the number of the slot groups 60 in the circumferential direction is seven, and as illustrated in FIG. 4, a plurality of plasma modes corresponding to the slot groups are generated. However, since the number of the slot groups is an odd and prime number, no lower order mode plasma than the number of slot groups is not generated. Thus, TM11 is not generated. Therefore, it is possible to generate plasma with high uniformity in the circumferential direction and to perform a plasma processing with high uniformity.

When a film is formed by plasma CVD as a plasma processing, a gas for film formation is excited by plasma and reacted on the surface of the wafer W as a workpiece, and if necessary, a high frequency bias for ion attraction is applied from the high frequency power supply 9 at a predetermined power to form a predetermined film. For example, in a case of forming a SiN film, a plasma generating gas, for example, a rare gas (e.g., Ar gas) is supplied from the gas supply mechanism 16 via the gas introduction portion 15 to generate microwave plasma. Then, a silicon source gas (e.g., monosilane (SiH₄) or disilane (Si₂H₆)) and a nitrogen-containing gas (e.g., N₂ or NH₃) are excited by the plasma and reacted on the surface of the wafer W.

In this case, as described above, since the slot 32 is provided such that the number of the slot groups in the circumferential direction is an odd number of three or more, the TM11 mode, which is a low-order mode, is not generated. Therefore, it is possible to perform a film formation process with high uniformity of plasma in the circumferential direction and high film thickness uniformity in the circumferential direction.

The film thickness uniformity in the circumferential direction may be obtained by the thickness distribution in the circumferential direction at a predetermined radial position of the wafer W and may be obtained by oval skew (ellipticity) as an index thereof. The oval skew is expressed in percentage how far the thickness distribution in the circumferential direction is away from the perfect circle. As in this embodiment, the value of the oval skew may be reduced by setting the number of slot groups in the circumferential direction to an odd number in the planar antenna. In a case where a SiN film is formed by plasma CVD, the value of the oval skew in the circumferential direction may be set as small as 1.7% or less.

<Test Result>

Next, a test result will be described.

In the microwave plasma processing apparatus illustrated in FIG. 1, a SiN film was formed by plasma CVD using a planar antenna having the slot pattern of the present disclosure illustrated in FIG. 2 and a conventional planar antenna illustrated in FIG. 5. The SiN film was formed at a microwave power of 2,000 to 5,000 W, a processing temperature of 200° C. to 600° C., and a processing pressure of 5 Pa to 100 Pa by using Ar gas as a plasma generating gas, SiH4 as a Si source gas, and N2 gas as a nitrogen-containing gas.

The conventional planar antenna of FIG. 5 has three circumferentially formed portions in the circumferential direction where slot pairs in a truncated chevron shape are formed in the radial direction, and the number of slot groups in the circumferential direction is eight, which is the smallest number in the innermost portion.

A SiN film was formed on a plurality of wafers using each planar antenna, and the uniformity of the film thickness in the circumferential direction was obtained. Oval skew was used as an indicator of circumferential uniformity of the film thickness.

The oval skew was determined as follows.

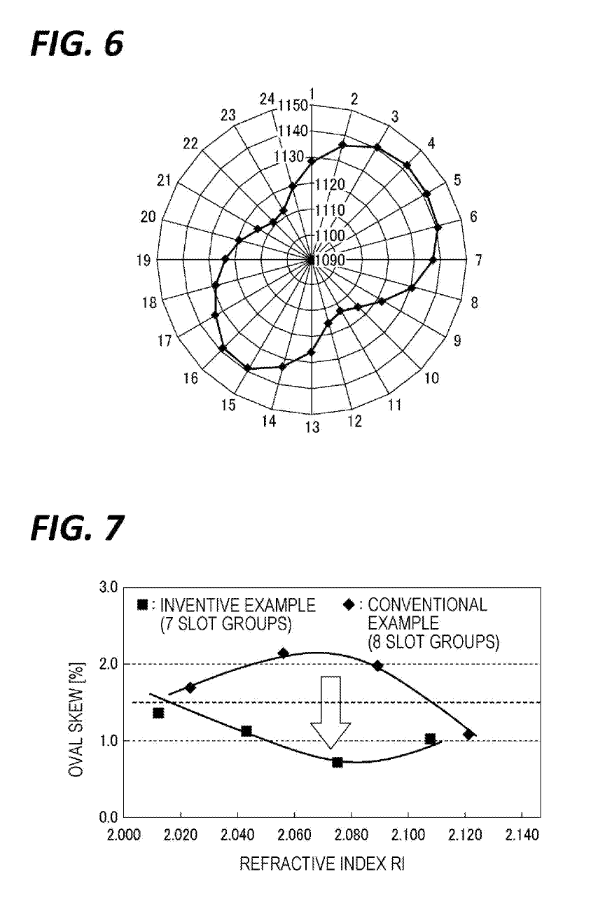

As illustrated in FIG. 6, twenty four points are set to be equally spaced in the circumference of the wafer, a film thickness (angstrom) at a position of a radius of 147 mm far from the center is obtained, and the average value of film thicknesses at two opposed positions is sequentially obtained.

That is, the following calculations were sequentially performed:

(film thickness at position 1+film thickness at position 13)/2=1127.1

(film thickness at position 2+film thickness at position 14)/2=1134.8

(film thickness at position 3+film thickness at position 15)/2=1140.0

(film thickness at position 4+film thickness at position 16)/2=1140.5

and

(film thickness at position 12+film thickness at position 24)/2.

Then, the maximum value, the minimum value, and the average value of the obtained 12 pieces of data were calculated. Then, the oval skew was calculated by the following equation:

Oval skew=(Maximum value−Minimum value)/Average value×100(%)

As the value of the oval skew is decreased, the film thickness distribution approaches the perfect circle, and the film thickness uniformity in the circumferential direction is enhanced.

The result of the oval skew is illustrated in FIG. 7. FIG. 7 is a graph illustrating a relationship between the film quality of the obtained SiN film (the value of the refractive index RI) (on the horizontal axis) and the value of the oval skew (on the vertical axis) with respect to the inventive example using the planar antenna having seven slot groups as illustrated in FIG. 2 and a conventional example using the planar antenna having eight slot groups as illustrated in FIG. 5.

As illustrated in FIG. 7, in the case of the conventional example in which the TM11 mode was generated, the oval skew was mostly over 1.7%. On the other hand, in the case of the inventive example in which the TM11 mode was not generated, the value of oval skew was lower than 1.7%.

From the result, it is confirmed that when the number of slot groups in the circumferential direction is set to be odd, the process uniformity is higher than that in the case of an even number.

### OTHER APPLICATIONS

For example, in the exemplary embodiment, the plasma CVD has been described as an example of the microwave plasma processing, but the present disclosure is not limited thereto. The present disclosure may also be applied to other plasma processing such as, for example, plasma etching, plasma oxidation processing, or plasma nitriding processing.

Further, the workpiece is not limited to the semiconductor wafer as long as process uniformity in the circumferential direction is required, and may be another workpiece such as, for example, a glass substrate or a ceramic substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A microwave plasma processing apparatus comprising:
a chamber that accommodates a workpiece;
a microwave generating source that generates microwaves;
a waveguide unit that guides the microwaves generated from the microwave generating source toward the chamber;
a planar antenna made of a conductor having a plurality of slots that radiate the microwaves guided by the waveguide unit toward the chamber;
a microwave-transmitting plate made of a dielectric material that constitutes a top wall of the chamber and transmits the microwaves radiated from the plurality of slots;
a gas supply mechanism that supplies a gas into the chamber; and
an exhaust mechanism that exhausts an atmosphere in the chamber,
wherein the planar antenna includes a plurality of slot groups each forming one unit including one or more of the slots, and
the slots are formed so as to form an odd number of slot groups equal to or more than three in a circumferential direction.

2. The microwave plasma processing apparatus of claim 1, wherein the slots are formed so as to form a prime number of slot groups in the circumferential direction in the planar antenna.

3. The microwave plasma processing apparatus of claim 2, wherein the slots are formed so as to form seven slot groups in the circumferential direction in the planar antenna.

4. The microwave plasma processing apparatus of claim 1, wherein the waveguide unit includes: a rectangular waveguide that propagates the microwaves generated from the microwave generating source in a TE mode; a mode converter that converts the TE mode to a TEM mode; and a coaxial waveguide that propagates the microwaves converted into the TEM mode toward the planar antenna.

5. The microwave plasma processing apparatus of claim 1, wherein, in the microwave plasma processing, the gas supply mechanism supplies a film forming gas into the chamber to form a predetermined film on the workpiece by plasma CVD.

6. The microwave plasma processing apparatus of claim 5, wherein the film forming gas supplied from the gas supply mechanism includes a silicon source gas and a nitrogen-containing gas, and a silicon nitride film is formed on the workpiece.

7. The microwave plasma processing apparatus of claim 6, wherein the silicon nitride film is formed at 1.7% or less in terms of oval skew which is an index of a circumferential film thickness distribution.

8. A microwave plasma processing method comprising:
accommodating a workpiece in a chamber;
guiding, by a waveguide unit, microwaves generated from a microwave generating source;
radiating the microwaves guided by the waveguide unit from a plurality of slots formed in a planar antenna made of a conductor through a microwave-transmitting plate made of a dielectric constituting a top wall of the chamber;
supplying, by a gas supply mechanism, a gas into the chamber to generate plasma in a lower portion of the microwave-transmitting plate by the microwaves; and
performing a predetermined processing on the workpiece by the plasma,
wherein the planar antenna includes a plurality of slot groups each forming one unit including one or more of the slots, and
the slots are formed so as to form an odd number of slot groups equal to or more than three in a circumferential direction.

9. The microwave plasma processing method of claim 8, wherein the slots are formed so as to form a prime number of slot groups in the circumferential direction in the planar antenna.

10. The microwave plasma processing method of claim 9, wherein the slots are formed so as to form seven slot groups in the circumferential direction in the planar antenna.

11. The microwave plasma processing method of claim 8, wherein the waveguide unit includes: a rectangular waveguide that propagates the microwaves generated from the microwave generating source in a TE mode; a mode converter that converts the TE mode to a TEM mode; and a coaxial waveguide that propagates the microwaves converted into the TEM mode toward the planar antenna.

12. The microwave plasma processing method of claim 8, further comprising:
supplying, by the gas supply mechanism, a film forming gas into the chamber to form a predetermined film on the workpiece by plasma CVD.

13. The microwave plasma processing method of claim 12, wherein the film forming gas supplied from the gas supply mechanism includes a silicon source gas and a nitrogen-containing gas, and a silicon nitride film is formed on the workpiece.

14. The microwave plasma processing apparatus of claim 13, wherein the silicon nitride film is formed at 1.7% or less in terms of oval skew which is an index of a circumferential film thickness distribution.
